(19) United States
(12) Patent Application Publication
(10) Pub. No.: US 2008/0308090 A1
(43) Pub. Date: Dec. 18, 2008

(54) Solar Concentrator

(76) Inventor: Barry Clive, Somerset (GB)

Correspondence Address: FISH & RICHARDSON, PC, P.O. BOX 1022, MINNEAPOLIS, MN, 55440-1022, US

(21) Appl. No.: 11/916,447

(22) PCT Filed: Jun. 2, 2006
(86) PCT No.: PCT/GB2006/002021

§ 371 Date: Jul. 21, 2008

(30) Foreign Application Priority Data
Jun. 3, 2005 (GB) 0511366.7

(51) Int. Cl. F24J 2/38; H01L 31/052; F24J 2/04; F24J 2/08; F24J 2/10

(52) U.S. Cl. 126/573; 136/259; 126/634; 126/683; 136/246

(57) ABSTRACT

A window unit comprising at least one transparent pane, a frame 130 around the perimeter of the at least one transparent pane, at least one rotatable linear concave mirror 110 extending at least partially across the frame, and at least one energy conversion device 120 extending at least partially across the frame wherein the unit is arranged such that substantially parallel radiation incident on the mirror is reflected onto the energy conversion device.

### PRIORITY CLAIM AND RELATED PATENT APPLICATION

This application is a 371 application of and claims priority to International Patent Application No. PCT/GB2006/002021, filed Jun. 2, 2006, which claims priority to Great Britain Patent Application No. 0511366.7, filed Jun. 3, 2005. The contents of the prior applications are considered part of and are incorporated by reference in the instant application.

### TECHNICAL FIELD

The present invention relates to solar concentrators.

### BACKGROUND

The depletion of fossil fuels and concerns of greenhouse gas emissions have prompted scientists to investigate alternative sources of energy. One option which has been investigated intently in recent years is that of generation of electricity from solar radiation.

Conventional solar panels are expensive and, operating at one sun concentrations, are inherently inefficient. Therefore, large and expensive panels are required to generate any useful amount of energy.

More recently, solar concentrators have been developed in which systems use mirrors to concentrate solar radiation onto photovoltaic cells. Such concentrated radiation provides the potential of higher power output per unit area of cell. However, concentrator solar cells are expensive. Additionally, such systems often incorporate tracking systems to allow the mirrors to track the sun which increase the complexity and cost of the system. Such systems are often delicate and require regular maintenance due to damage and wear by the elements.

### SUMMARY

We have appreciated that it would be beneficial to provide a solar concentration system which is relatively cheap to manufacture, can be produced in large quantities with relatively low technology manufacturing methods, is efficient in production of electricity and is sufficiently versatile to be integrated into domestic homes or offices as well as standing alone in remote locations. Such a system should also be hard wearing and not require regular maintenance.

Embodiments of the present invention provide a window frame unit comprising a frame and a transparent pane. Such embodiments comprise at least one rotatable concave mirror positioned on the inside of the pane and extending at least partially across the pane, and at least one energy conversion device which extends at least partially across the pane. The unit is adapted such that substantially parallel radiation incident on the mirror is reflected onto the energy conversion device. The energy conversion device may be positioned on the outside of the pane or within glazing bars where the pane is formed by a plurality of strips of glass or other transparent material. Preferred embodiments include a double glazed unit in which the mirror is positioned between the panes. Such embodiments provide the advantage that the mirrors and moving components are protected from the elements. Thus, cheaper mirrors and components can be used since they do not need to withstand the effects of the elements. Such embodiments can be integrated into walls and roofs or used as a stand alone unit in a remote and exposed location.

Further embodiments of the present invention concentrate substantially parallel solar radiation by reflecting incident radiation using a linear concave mirror onto a secondary optic which contains a lens and an energy conversion device. The secondary optic has an aperture for capturing the reflected radiation and radiation passing into the aperture is directed onto the energy conversion device. The mirror is rotatable to different positions to track the sun and reflect incident radiation into the aperture. Such embodiments provide the advantage that the secondary optic further relaxes the requirement for a mirror to have a common focal point for all angles of rotation and a directing lens in the secondary optic can both increase the concentration of solar radiation and facilitate the use of small energy conversion devices. Both advantages provide a reduction in manufacture costs.

The invention is defined in its various aspects in the appended claims to which reference should now be made.

### BRIEF DESCRIPTION OF DRAWINGS

An embodiment of the invention is described in detail with reference to the accompanying drawings in which:

FIG. 1 is a representation of an embodiment of the present invention.

FIG. 2 is a cross-sectional representation of the optical arrangement of a single mirror and a secondary optic used in embodiments of the present invention.

FIG. 3 shows the angle of incidence of solar radiation at different times of the day between sunrise and sunset.

FIG. 3a shows the angles of reflection of incident radiation at oblique angles.

FIG. 4 shows a mirror having reflecting protrusions.

FIGS. 5a, 5b and 5c are representations of secondary optics used in embodiments of the present invention.

FIG. 6 shows the connection of a plurality of photovoltaic cells used in embodiments of the present invention.

FIGS. 7a, 7b and 7c show arrangements of secondary optics used in embodiments of the present invention.

FIG. 8 shows the dimensions of an optical arrangement used in a specific embodiment of the present invention.

### DETAILED DESCRIPTION

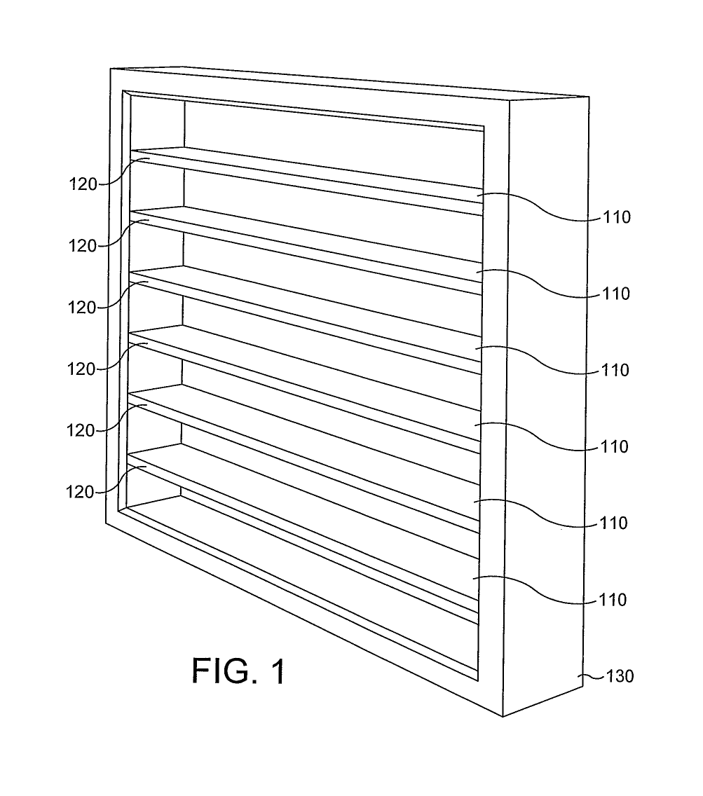

FIG. 1 is a representation of a first embodiment of the present invention which is designed to direct and concentrate substantially parallel radiation, for example from a distant source, for example the sun, onto photovoltaic cells in order to produce electricity. The embodiment of FIG. 1 has dimensions similar to those of a window unit and has a frame 130 and first and second transparent panes. The embodiment of FIG. 1 includes a plurality of mirrors 110 which extend across the width of the frame. The mirrors reflect solar radiation onto corresponding photovoltaic cells. The photovoltaic cells used extend at least partially across the unit. The photovoltaic cells are positioned within secondary optics 120. The secondary optic includes a photovoltaic cell, a lens for capturing the reflected radiation and for directing the radiation onto the photovoltaic cell and a heat sink in thermal contact with the photovoltaic cell.

The mirrors are concave and extend linearly across the unit. They are arranged in a venetian blind style configuration and each is rotatable about an axis parallel to its length in order that it can track the movement of the sun along one axis to follow its elevation during the day. The system is designed to reflect incident radiation onto the secondary optic for all rotational positions of the mirror. In order to optimise the radiation reflected and captured by the device during the day, the mirrors are aligned in the East-West direction and the mirrors rotate in the North-South direction.

Preferred embodiments of the invention are designed to be integrated into buildings by being placed in window frames, either as a skylight in a roof or in a vertical wall. Such embodiments collect direct sunlight while allowing diffused light to pass into the building. In preferred embodiments of the invention, the frame is made from commercially available window frame extrusions. The mirrors and secondary optics are supported within the frame and extend across the width of the frame. The mirrors and moving parts are positioned between the panes in order to protect them from damage, environmental or otherwise, and the effects of the elements. In the embodiment of FIG. 1, the secondary optics are positioned externally to the window unit and attached to the outside of the pane. Thus the heat sink of the secondary optic is brought into contact with the elements.

Preferred embodiments of the invention position the mirrors and moving components in a contained environment to protect the mirrors from the external elements. This is particularly important since the mirrors should be angled accurately with respect to the cell and the sun and, additionally, contact with wind or rain may affect the alignment of the mirrors. Additionally, the surface of the mirror should be kept clean in order to maximise the reflection potential for the mirror. Embodiments in which the mirrors are protected from the elements can also be fabricated using lighter and lower cost materials and using a more economical production process. Each of these features can reduce both financial and lifecycle costs. Additionally, the tracking, drive, linkage and mirror support systems can all be made with lower cost materials and components.

Conversely, the heat sink should be positioned in a cool environment. Therefore, the heat sink benefits by being positioned in contact with the elements. Preferred embodiments of the present invention combine these benefits by positioning the secondary optic on the outside of a window and the mirrors and other moving parts on the inside of the window. Untreated glass or Perspex is ideal for such an arrangement since it protects the mirrors and moving parts from the elements while not preventing light from reaching the mirrors.

The transparent panes can attenuate the incident radiation. Typically, acrylic sheet reduces the solar radiation incident on the mirrors by around 8% although it is possible to apply high transmission coatings to glazing to reduce this loss to less than 2%. Simple untreated glass provides an attenuation factor of up to around 16% but the optical performance can be improved by using a low-iron coated glass.

Further embodiments may not include the panes but, instead, support the mirrors and secondary optics by the frame or have a single pane, behind which the mirrors and moving components are positioned. The embodiment of FIG. 1 may include a support stand to enable the unit to be freestanding although, as discussed above, embodiments of the invention may be integrated into a building.

In preferred embodiments of the invention the photovoltaic cells are connected together in order to provide a single power output.

Although the embodiment of FIG. 1 includes six mirrors and corresponding secondary optics, further embodiments of the invention could comprise a single mirror and secondary optic or any other number mirror and secondary optics depending on the design constraints for the device or the required performance.

The components of an embodiment of the invention and further design considerations are now discussed in detail with respect to the remaining figures.

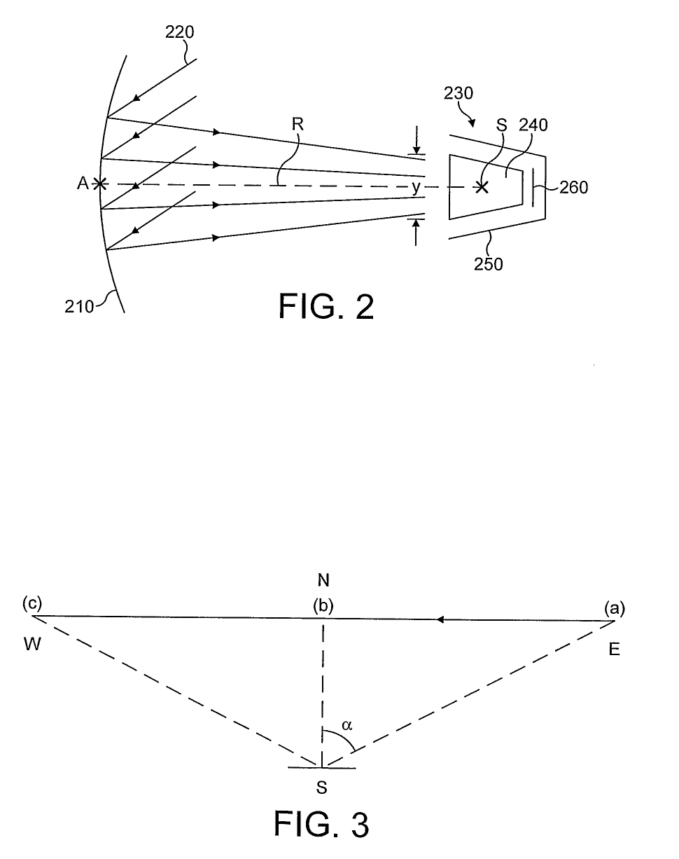

FIG. 2 depicts the basic optical arrangement used in embodiments of the present invention. Specifically, FIG. 2 shows a cross-sectional representation of a mirror and corresponding secondary optic. The mirror 210 is concave and its cross section is the arc of a circle. Further embodiments may include mirrors with parabolic cross-sections which are capable of producing a higher concentration of reflected radiation. The mirror should be sufficiently stiff so that it does not twist or bend along its length and maintains a constant angle along its length with respect to the sun and the secondary optic.

Mirrors may be manufactured by being pressed out of a sheet of aluminium. Typically the shape of the press should allow for material “spring back” once the press is released. The mirrors can then be coated with a reflective material to increase the reflection of the radiation. Ideally, materials should be selected with reflection efficiencies of at least 90%. Preferred embodiments include mirrors comprising reflective surfaces made of VM2000 (produced by 3M) laid over an aluminium substrate.

An advantage of embodiments in which the mirrors are positioned behind a transparent pane or between a pair of panes, and, hence, are protected from the elements is that typical plastic mirrors which are mass produced for use in indoor fluorescent lighting systems can be used. Such plastic mirrors includes prism film structures. Such mirrors would not be hardwearing enough for outdoor use but are suitable for use in embodiments in which the mirrors are sheltered from the elements. The plastic mirrors provide a cheap component compared with more robust mirrors designed for outdoor use.

The mirror reflects solar radiation 220, which is incident on the mirror, towards the secondary optic 230. The mirror is rotatable about an axis which is parallel to its length and positioned on the line (R) joining the centre of curvature (A) on the surface of the mirror 210 (the vertex of a parabolic mirror) to the centre point (S) of the secondary optic 240. Examples of how the mirrors are rotated include by being pivoted to the frame at a suitable position or being hung from a roller in a typical Venetian blind style. As the sun changes its angle of elevation during the day, the mirror rotates to track the sun and continue to reflect the incident radiation onto the secondary optic. The position of the mirror with respect to the secondary optic, curvature of the mirror surface and axis of rotation of the mirror are selected such that as the mirror rotates between its extreme angles of rotation it continues to reflect the incident solar radiation onto the secondary optic 230. In preferred embodiments of the invention, the axis of rotation is close to the mirror itself. The extreme angles of rotation of the mirror should be sufficient to reflect the solar radiation towards the secondary optic during at least the middle six hours of the day even at mid winter and mid summer.

At midday in mid summer, the angle of the sun to the vertical is 23.5° less than the angle of latitude of the place at which it is viewed. For example, in London (51.5° latitude) the angle is 28°. At midday in mid winter the angle of the sun is 23.5° more than the latitude at which it is viewed. For example, in London the angle will be 75°. At summer and winter solstices, in order to capture sunlight for several hours either side of midday the angle is decreased and increased by at least 12° respectively. The angle through which the mirror is required to rotate in order to cover those extremes varies depending on whether the axis of rotation is at the mirror, at the secondary optic or at some point in between.

The secondary optic 230 comprises a lens 240, a photovoltaic cell 260 located behind the lens and a heat sink 250. The secondary optic has an aperture of width y and receives radiation which is incident on the secondary optic and falls within the aperture. The secondary optic is designed, and the lens positioned, such that any radiation entering the secondary optic through the aperture is directed onto the photovoltaic cell. Ideally, the radiation should be incident onto the photovoltaic cell at an equal concentration across its whole surface. Such arrangements produce less heating of the cell compared with the situation in which the same number of photons is focussed onto a small area of the cell producing a localised high concentration which is not evenly distributed across the surface of the cell. Thus, preferred embodiments of the lens act to diffuse the incoming radiation to provide equal concentration of incident radiation over the whole surface of the cell. Embodiments without secondary optics which rely on the mirrors to focus the radiation onto the cells can produce very concentrated focal lines onto very localised areas of the surface of the cell which reduces the efficiency of the cell.

The photovoltaic cell is placed in thermal contact with the heat sink 250. Embodiments of the invention use suitable adhesives, for example Chomerics Thermattach tape. In preferred embodiments of the invention, the secondary optic and the contained photovoltaic cell run along the entire width of the unit opposite the corresponding mirror.

FIG. 2 represents a typical cross-section through the mirror and secondary optic. It will be clear that the mirror, lens and heatsink extend along the width of the unit although embodiments may include breaks or gaps in any of the components.

The positioning of the mirror and secondary optic and the curvature of the mirror are selected to enable a maximum amount of radiation incident on the mirror to be reflected into the secondary optic and, hence, directed onto the surface of the photovoltaic cell, for all possible angles of rotation of the mirror with respect to the secondary optic. Typically, embodiments should capture at least 80% of the reflected radiation Thus, the curvature of the mirror, distance between the mirror and the secondary optic, size of the aperture of the optic and the centre of rotation of the mirror are all inter-related as design parameters.

The optimum angle between the face of the mirror and the incident radiation for reflecting incident radiation onto the secondary optic at different rotational positions will depend on the axis of rotation and curvature of the mirror. However, when the axis of rotation is close to the mirror, the plane normal to the centre of the mirror should bisect the angle between the centre of curvature on the face of the mirror (A) and the sun and the centre of curvature on the face of the mirror (A) and the centre of the secondary optic (S).

Embodiments of the invention which are designed in dimensions matching those of window units require a shallow depth, i.e. narrow distance between the double glazed window panes or single window or mirrors. In such cases, mirrors should have focal lengths of up to around 80 mm.

The finite aperture width y of the secondary optic, within which reflected radiation is captured, relaxes the requirement for the mirror to have the same, physical position for its focal point for all angles of rotation. Instead, the only requirement is for the radiation to be reflected to within the aperture. By employing a secondary optic having a finite aperture width rather than reflecting the radiation directly on to the photovoltaic cell the restraints of the system are reduced. In particular, it is acceptable for the physical focal point of the mirror to change for different positions of rotation as long as an acceptable percentage of the reflected radiation is captured by the secondary optic. Thus, a coma may be produced for different rotational positions of the mirror. A coma is produced if the mirrors are not rotated about their focal line and the position of the coma can be optimised such that radiation is reflected into the secondary optic for all allowable angles of rotation of the mirror. Thus, the inclusion of the secondary optic having an aperture for capturing incident radiation facilitates the use of cheaper mirrors and, hence, enables the overall cost of the system to be reduced. Additionally the secondary optic permits more cheaply constructed tracking systems which rotate the mirrors about an axis close to its centre of curvature on the face of the mirror. The secondary optic generally permits less precise tracking for a given concentration or higher concentration for a given tracking accuracy. Higher concentration allows a smaller and, hence, cheaper photovoltaic cell to be used.

Although embodiments incorporating a lens are preferred, alternative embodiments may reflect the radiation directly onto the heat transfer medium without requiring a lens.

Further embodiments of the invention may replace the photovoltaic cell with a heat pipe carrying a heat transfer medium. Such a heat pipe may use evaporation and subsequent condensation to transfer the heat away from the optical system along the heat pipe. Alternatively, the photovoltaic cell may be replaced by an active system through which water is pumped. Either of those arrangements could allow the heat transfer fluid within the pipe to reach high enough temperatures to drive a turbine and generate electricity. In the case of a heat pipe, to maximise temperatures, a thin vacuum tube may enclose the pipe. In such embodiments the heat pipe could be enclosed within the glazed unit.

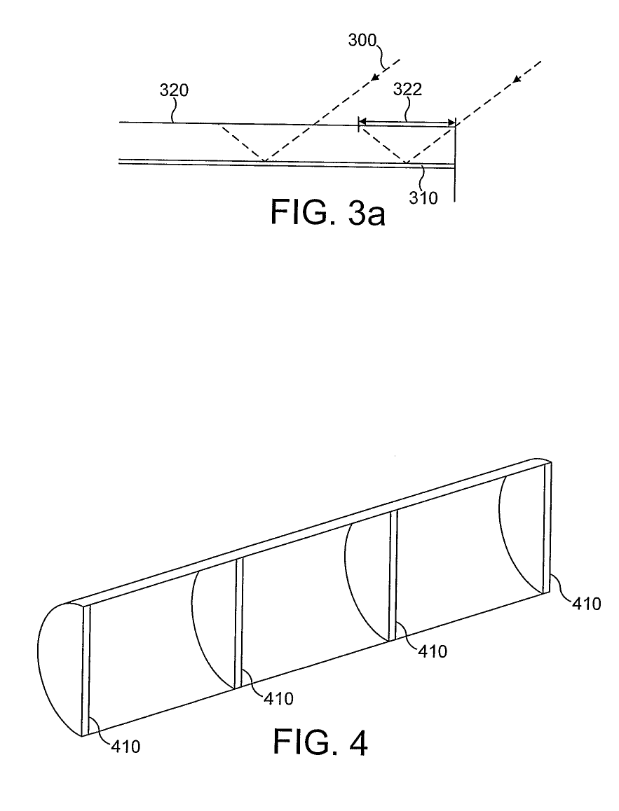

During the day, the position of the sun in the sky moves horizontally from East to West as well as increasing and decreasing in angle of elevation. FIG. 3 shows an example of the horizontal path of the sun with respect to a unit aligned East-West from a top perspective and indicates the azimuth angle a between the sun and the North-South line normal to the unit. The azimuth angle decreases from sunrise (a) to zero at around midday (b) and increases again as sunset is approached (c). The changing azimuth angle, and hence angle at which radiation is incident upon the mirrors, change the angle of reflection of the radiation by the mirrors. As shown in FIG. 3a, at times around sunset and sunrise the azimuth angle is largest and, hence, the angle between the incident radiation 300 and the face of the mirror 310 is smallest. During these periods there will be regions 322 of the photovoltaic cell which are not illuminated by reflected radiation. Thus, the active length of the cells will be reduced during these periods. In order to help to reflect radiation onto these areas of the cell during these periods, preferred embodiments of the invention include reflective protrusions extending from the front of the mirrors and positioned along the length to reflect radiation back onto the non-illuminated areas. In preferred embodiments, the protrusions take the form of sections of disks and extend substantially perpendicularly to the surface of the mirror. The protrusions are shown as 410 in FIG. 4. Further embodiments include mirrors positioned on the inside surfaces of the frame of the unit to reflect radiation back onto the mirrors.

Another problem with large azimuth angles is that the attenuation of radiation due to the transparent panes increases due to the refractive index of the pane and reflection of the incident radiation by the transparent pane. These losses are referred to as cosine losses. Thus, the efficiency of the system decreases as the azimuth angle increases.

In order to maximise light capture, the system should be south facing inclined at latitude angle. The rising and setting positions of the sun at most latitudes would be at positions so far east and west that there would be little light capture due to cosine losses. Thus, embodiments are designed to work efficiently for around six hours each day.

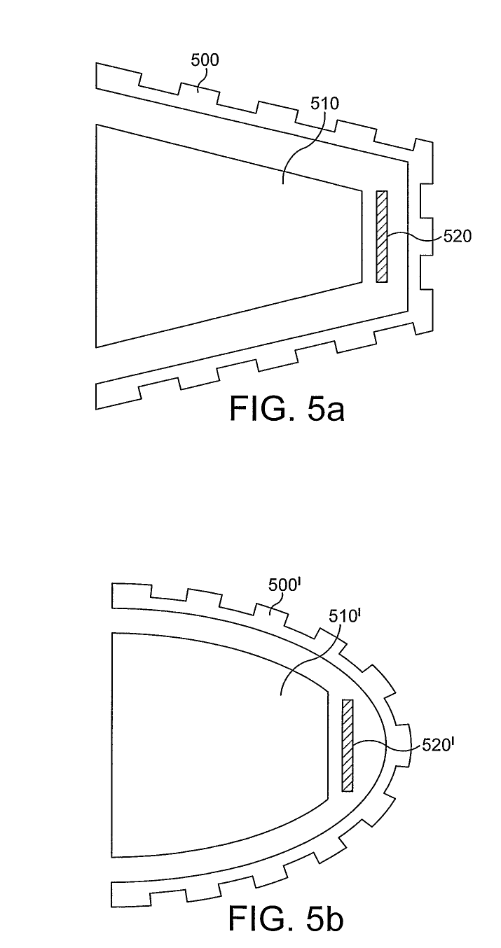

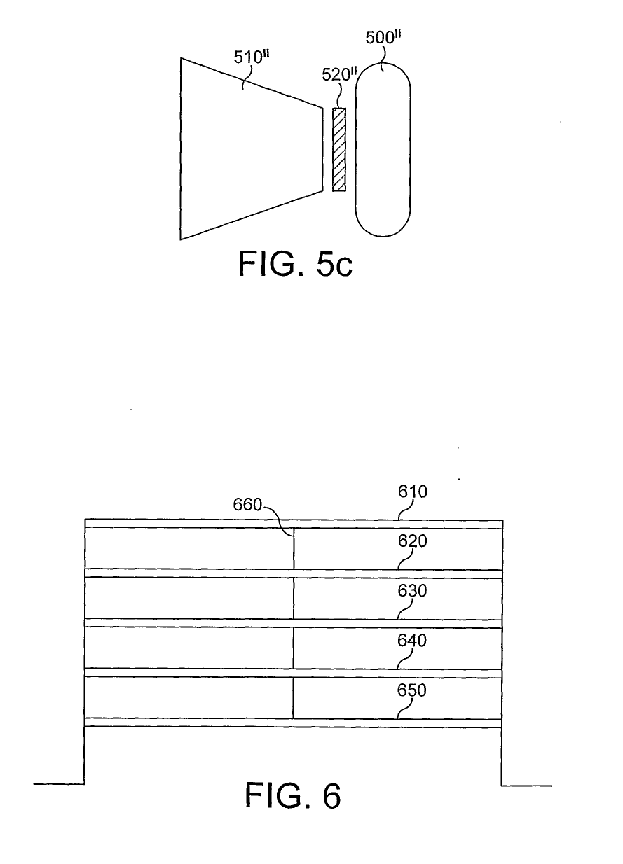

FIGS. 5a, 5b and 5c are cross-sectional representations through three different embodiments of secondary optics used in embodiments of the present invention. Each of the embodiments comprises a heat sink 500, 500′, 500″, a lens 510, 510′, 510″ and a photovoltaic cell 520, 520′, 520″. The heat sink is placed in thermal contact with the cell. An important feature of all embodiments of the secondary optic is that radiation reflected into the secondary optic is directed onto the photovoltaic cell. This can be achieved by total internal reflection within the lens or by reflection by the inside surface of the heat sink. The more accurately that the lens or heat sink can direct the incident radiation onto the photovoltaic cell, the smaller the photovoltaic cell that can be employed in the invention. It is advantageous to reduce the size of the photovoltaic cell since the photovoltaic cell accounts for a significant function of the overall cost and this will reduce the overall cost of the device. Additionally, higher concentrations of radiation on the photovoltaic cell produce higher electric currents. Preferred embodiments diffuse the incoming radiation to provide an equal concentration over the surface.

The embodiments of FIGS. 5a and 5b incorporate a heat sink which contains the lens. Such embodiments can rely on total internal reflection of incident radiation within the lens or reflection from the inside surface of the heat sink or a combination of total internal reflection and reflection from the heat sink. In preferred embodiments of the invention the inside surface of the heat sink is polished or coated with a highly reflective material. In such embodiments, the angle of the sides of the heat sink is selected in order to enable the radiation to be directed on to the cell. Preferred embodiments have tapered sides or curved sides as shown in FIGS. 5a and 5b respectively. An advantage of embodiments in which the lens is contained within the heat sink is that the lens and photovoltaic cell are protected from damage from the elements. This also reduces the requirements for cleaning the lens and increases the overall physical strength of the secondary optic.

In embodiments of the invention, the mirror either rotates about the line of the focus about 36 degrees either way or it moves about an axis close to its geometrical centre about 18 degrees either way. The object of the design of the outside of the heat sink is to minimise the shading losses when the sun is between 36 degrees above and below the centre line. A shape similar to an equilateral triangle will therefore minimise the shading losses so the maximum surface area of heat sink should fit within this profile.

Preferred embodiments use aluminium extrusions, typical of electronics applications, for the heat sink due to its heat conductivity. Alternatively magnesium castings could be used. In fact, any material having suitable heat conductivity could be employed. In certain embodiments, where the extrusion is not providing any strength, it is possible to split the heat sink and mount the cells directly onto the heat sink rather than having the expense of electrically isolating the heat sink from the cells, where this is required for series connection of the cells string.

Preferably, acrylic (PMMA) is used for the lens although any other transparent polymers or glass with suitable properties could be used. Such materials are readily available, cheap and easy to mould. Again, these properties help to reduce the overall cost of the device.

In the arrangements of FIGS. 5a and 5b, the heat sink simply dissipates heat into the atmosphere. In FIG. 5c, however, the heat sink 500″ is a heat pipe carrying a heat transfer medium which is thermally connected to the photovoltaic cell 520″. Typical materials for fabrication of the pipe include copper or, if used at higher pressures, steel. In preferred embodiments, the pipe carries either air or water in order to reduce costs of the system. After absorbing the heat from the photovoltaic cells, the coolant could be used to heat water. In this case, since the heat pipe cools the cells, ambient air is not needed and so the secondary optic could be completely enclosed within the glazing. In an alternative arrangement (not shown), the heat sink is an active system through which water (or another fluid) is pumped i.e. a non-closed system. In that case, the water can be used itself as hot water or alternatively may be used to heat other water.

In preferred embodiments, the heat sinks extend along the length of the photovoltaic cell and across the width of the frame. In further embodiments, the heat sinks may be connected to further heat sinks positioned on the frame in order to further improve the extraction of thermal energy from the photovoltaic cells.

Preferred embodiments of the present invention employ photovoltaic cells using typical one-sun technology and manufacturing processes. One-sun cells are designed to operate at one concentration of solar radiation. However, due to the concentrations produced by embodiments of the invention (in excess of ×10) the cells should be modified to maximise efficiency. Preferred embodiments employ Solartec concentrator cells, BP cells or one-sun cells modified using laser buried grid technology developed by BP Solar.

An advantage of the present invention is that cells can be used which in volume could be the same price as mass produced one-sun cells. Typically monocrystalline silicon cells are used with fine grid lines which are closely spaced and which do not cause excessive shadowing of the cell surface. Screen printing of grid lines may also be suitable. Alternatively, thin film cadmium telluride cells may be used.

The efficiency of the monocrystalline silicon cells is dependent on temperature. Typically, the cells are designed to operate at ambient temperature of around 25° C. As the temperature of the cell increases above ambient, the efficiency of the cell is reduced. Typically, the photovoltaic cells experience a fairly linear temperature dependence of around ½% reduction in efficiency per 1° C. increase above ambient temperature. Therefore, it is important to ensure that the photovoltaic cells are cooled as efficiently as possible in order to optimise performance of the cells and, thus, the selection of heat sink arrangement is an important design consideration. In practice, when hot water is needed the cells can be actively cooled to temperatures of around 60° C. which is around 18% lower efficiency than their normally rated temperature but provides the required temperature of hot water. This is seen as an acceptable compromise since, in some areas, ambient temperature can be as high as 40° C., thus 60° C. only presents a further 10% reduction in efficiency compared with these temperatures.

As the concentration of solar radiation on an area of cell increases, the temperature of that area of cell increases. The increase in temperature produces a decrease in efficiency which, consequently, leads to a temperature increase in the cell due to increased resistance. This circular effect increases the importance of the heat sinks. In particular, small photovoltaic cells operating at high concentrations will generate high levels of thermal energy. Heat sinks may also be connected to further heat sinks in order to improve the conduction of thermal energy away from the cells.

Typical embodiments of the invention are designed to operate at useful voltages for battery charging of around 12 or 24 V or higher for grid connection. An individual silicon cell generates a little over 0.5V and they can then be connected in parallel or series to raise the voltage or the current. One square meter of this system exposed to full sunlight normal to its surface will generate about 110-150 Watts depending on the efficiency of the cells, the cooling and the optical components.

Another consideration when selecting a particular solar cell is that it is capable of working efficiently at the concentration at which the system is designed to operate. For example, embodiments of the invention can be designed to produce concentrations of solar radiation of 20 or 30 times higher than one sun concentration at the photovoltaic cell. For higher concentration cells designed to produce more current, such as those produced by NAREC, would be suitable.

In order to prevent movement of the components of the secondary optic, a transparent encapsulant and optical link between the lens and the photovoltaic cell can be incorporated. Additionally, a similar optical link can be incorporated between the lens and the transparent panes. Si gel is a preferred encapsulant in embodiments of the invention although any suitable silicon elastomer or other suitable material could be used. The encapsulant should be transparent and be able to sustain the temperatures experienced by the photovoltaic cell. Conventional solutions of the electronic industry to link components to the heat sink are applicable to thermally connect the cell to the heat sink. The choice will depend on whether electrical conduction or isolation is required.

Embodiments of the present invention are designed to reflect solar radiation into the secondary optic. Thus, in most embodiments the solar radiation incident onto the mirrors is directed from behind the secondary optic. This design arrangement means that the secondary optic will block some of the incident radiation and, thus, prevent it from reaching the mirrors. Therefore, it is important to minimise the radiation blocked by the secondary optic. Additionally, since the sun moves with respect to the device and the optic is stationary, it is important to consider all angles of incidence when designing the secondary optic. Additional considerations are the latitude of the device, since at different latitudes the angle of elevation of the sun will vary. Embodiments designed for use at different latitudes are optimised at different angles of tapering. If the system is inclined perpendicular to latitude angle then there will be little difference in this respect for different latitudes. But if it is in a vertical wall for instance then there will needed a different inclination and position of the secondary to optimise incidence on the cell.

As mentioned above, in embodiments of the invention, in which the mirror either rotates about the line of the focus about 36 degrees either way or it moves about an axis close to its geometrical centre about 18 degrees either way, a shape similar to an equilateral triangle will therefore minimise the shading losses so the maximum surface area of heat sink should fit within this profile.

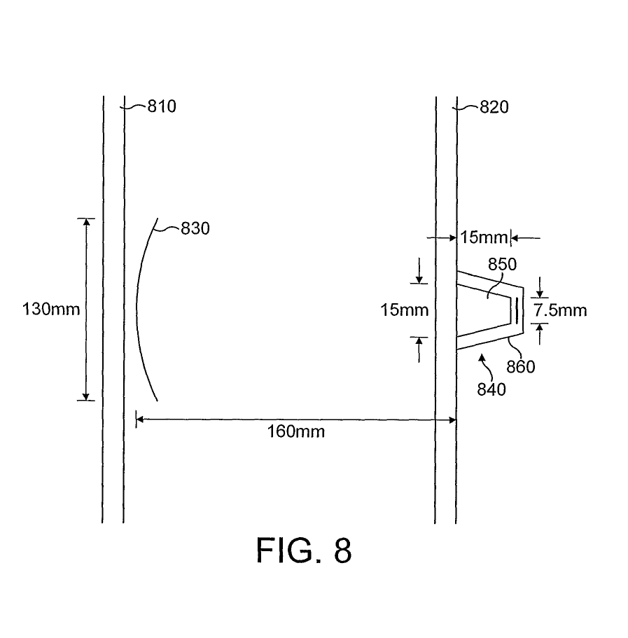

Additionally, the physical size of the aperture and secondary optic should be considered when considering the radiation that will be blocked by the secondary optic. There is clearly a design consideration between using a small aperture which produces a small footprint but requires an accurate mirror in order to capture a large portion of the reflective rays and a larger aperture which produces a larger footprint but will remove the requirement for having an accurate mirror. Additionally, as the size of the aperture is increased, the angle subtended between the mirror and the aperture is increased and, therefore, reduces the requirements of the tracking accuracy. Again, the cost of the system and required power output will be factors in determining the dimensions of the secondary optic. Examples of dimensions of the secondary optic and performance are provided below with reference to FIG. 8.

FIG. 6 is a basic circuit diagram representing the connection of photovoltaic cells 610-650 in an embodiment of the present invention. The photovoltaic cells 610-650 extend across the unit and are connected in parallel as shown in FIG. 6. However, in further embodiments the cells could be connected in series. The parallel connection provides the advantage that uneven illumination on the cells will not significantly reduce the output of all cells. In contrast, if connected in series, uneven illumination on the cells would reduce the output of the whole string to that of the least illuminated cell. If connected in parallel, when any one of the cells experiences a high resistance or break in connection then that cell can be bypassed without significantly reducing the current or performance of other cells, as would be the case if the cells were connected in series.

Further preferred embodiments provide electrical connections 660 across the cells. This technique reduces the size of the cells further and allows smaller inefficient sections to be bypassed.

The resistance of a particular cell may increase for a number of reasons, including overheating in the cell which may be caused by problems with the heat sink in the local area. Otherwise, breaks in the cell may occur, for example due to environmental damage. Other reasons that a particular cell may produce less current than other cells are if one cell receives less incident radiation, either due to the associated mirror being in a position in which its incident radiation is blocked or if the rotation mechanism for the mirror develops a fault and does not optimise the amount of radiation that is reflected onto the photovoltaic cell.

Preferred embodiments of the invention include a tracking system to automatically rotate the mirrors to follow the elevation of the sun. The mirrors rotate around an axis parallel to the length of the mirror as discussed above. In a preferred embodiment of the present invention, the mechanism driving the rotation of the mirrors is connected to a clock. The device is programmed with a database identifying the angle of elevation of the sun with respect to the device as a function of time and, thus, the required rotational angle of the mirror as a function of time. Such embodiments are relatively simple to implement and ensure that even if the sun is obscured during the day that the mirrors continue to follow the expected position of the sun and so are correctly aligned when the sun is exposed again.

Further embodiments incorporate standard open or closed loop solar tracking methods, or a combination of open and closed loop tracking methods, to enable the mirrors to track the sun during the day. The simple clock rotation system provides a cheap and reliable means of rotating the mirrors providing that the angular dependence on time is programmed correctly.

Further embodiments of the invention include a mechanism by which the mirrors are returned to their original position after the sun sets.

The driving mechanism for rotation of the mirrors may be provided by pivoting the mirrors at the frame and connecting the pivoted points of each mirror to a gear system which is subsequently connected to a driver. Alternatively, the mirrors may be hung in the style of a venetian blind, wherein the mirrors are hung from a roller at the top of the frame which rotates to rotate the mirrors.

Embodiments of the system which do not include tracking systems allow the mirrors to be rotated manually. Depending on how near to the solstices and the concentration required, movement may be up to three times a day. In the developing world this is quite acceptable and gives the security of easy maintenance and low cost. To minimise cosine losses due to the sun's diurnal movement the entire unit can be rotated around a polar axis and fixed in three positions. This is done for flat plate photovoltaic pumping systems in India to save money.

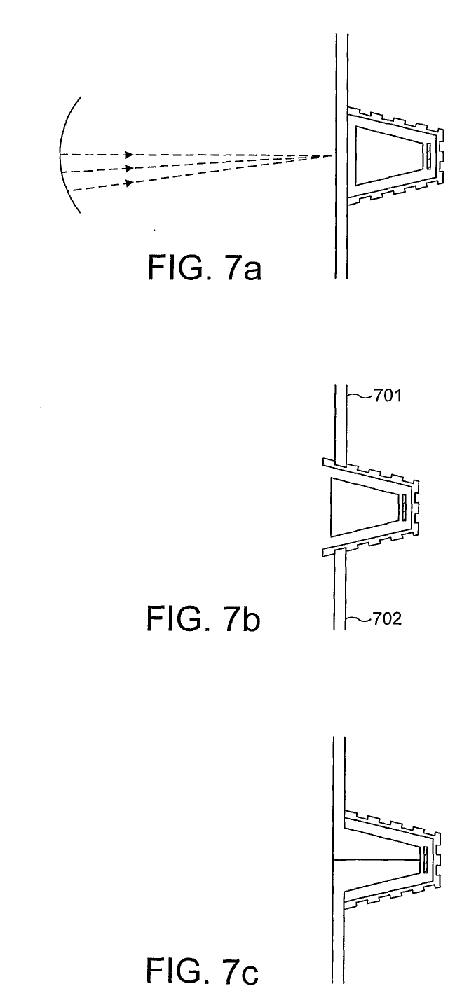

FIGS. 7a, 7b and 7c show different arrangements of the secondary optic and heat sink in different embodiments of the present invention. In FIG. 7a the secondary optic and heat sink are adhered to the outside of a window pane. In such embodiments it is important that the adhesive used is transparent and does not obscure the radiation from entering the lens. Such embodiments of the invention are relatively simple to construct although the secondary optic must be positioned accurately to capture the radiation reflected from the mirror.

In FIG. 7b the window pane comprises a series of strips of glass 701, 702 and the secondary optics are positioned between the glass strips. In this embodiment the heat sinks have the additional purpose of acting as glazing bars to support the window. Additionally, such embodiments have the advantage that reflected radiation does not have to pass through a glass pane before reaching the lens. Thus, any attenuation due to the glass pane between the mirror and the lens is removed. Additionally, the lens is positioned within the confined environment and, thus, protected. Additionally, the window material is less deep and therefore a thinner section can be used with consequent material savings. In such embodiments, the heat sink can be used as a glazing bar, although if parallel connection of cells was still needed some sort of electrical isolation between cells and heat sinks or sections of heat sink would be required.

The embodiment of FIG. 7c uses specially moulded glass or Perspex in order that the lens is integral with the window pane. The heat sink is positioned outside the moulded glass. Using a split secondary makes moulding and extrusion easier and cheaper as moulding is faster due the thinner wall section than a secondary made as one unit and assembly is easier and there are fewer components to the system.

FIG. 8 shows an example of a specific embodiment of the invention. The mirrors are completely enclosed within a double glazed unit having glass panes 810 and 820. The mirror 830 is 130 mm wide and 1 m in length. The distance between the centre of curvature on the face of the mirror and the secondary optic 840 is 15 cm. The lens 850 has an aperture of 15 mm and is tapered to 7.5 mm at the narrower end. The depth of the lens is 15 mm The heat sink 860 is fabricated from aluminium and positioned on the outside of the glass pane 820. Such a system is able to produce concentrations of ×20 at the photovoltaic cell.

The total optical efficiency of the system is calculated by the product of the attenuation due to the glass panes, the efficiency of reflection by the mirror and the percentage of reflected radiation that is captured by the secondary optic and directed onto the photovoltaic cell. Assuming that the glass has an attenuation factor of 16%, 91% of radiation incident on the mirror is reflected and 80% of the reflected radiation is directed onto the photovoltaic cell, the optical efficiency of the system is around 61%. This efficiency can be increased by using low-iron coated glass. The efficiencies of the photovoltaic cells mentioned above is around 16%. Therefore the total system efficiency is around 10%.

The total costs for the system as a stand alone unit are predicted to be in the region of $180 per 1 meter-squared unit, assuming that the most costly components, (i.e. the frame and the cells) are mass-produced. This translates into a value of $2.02 per watt peak. As a building integrated unit, assuming that the collector will displace a window of equal dimensions and performance, the system rating would increase to $1.27/Wp. Thus, embodiments of the present invention provide a cheaper alternative to solar panels, despite the efficiency being lower. The embodiment described is not yet optimised and higher efficiencies may be obtained with different sized components.

It will be clear to those skilled in the art that one of the important advantages of the present invention is its versatility for incorporation into various orientations of walls and roofs. Units positioned in vertical walls work efficiently but will not allow much ambient light between the mirrors. Whereas for European type latitudes incorporation into a horizontal roof will permit a great deal of ambient light into the building.

Preferred embodiments provide the additional advantage that all components which benefit from being positioned within a protected environment are positioned within a confined environment, for example the mirrors and moving components, and all components which benefit from being in an environment exposed to the elements are exposed, for example the heat sinks.

When the glazing of the system is not perpendicular to the latitude angle there needs to be a wider acceptance angle to not let any direct sunlight into the building. The secondary optic should be at a corresponding angle to the glazing.

Embodiments of the present invention provide a means for producing suitable power levels for domestic use at a reasonable cost by concentrating solar radiation onto photovoltaic cells at high concentrations. Embodiments reflect solar radiation onto a secondary optic which concentrates the radiation onto a photovoltaic cell. The secondary optic removes the requirement for high quality mirrors which have precise focal points by providing a finite aperture into which radiation is reflected and then directed onto the photovoltaic cell. Embodiments can easily generate at least ×8 concentrations although much higher concentrations are possible using different components and dimensions. Embodiments of the invention may be employed in a number of different environments, for example being integrated into a variety of differently inclined outer surfaces of a building or used as freestanding units, used only to generate power.

Embodiments of the invention may replace standard windows in buildings which, as well as producing electricity, also prevent the ingress of direct sunlight into the interior of the building while allowing ambient light to pass between the mirrors. Such embodiments help reduce the need for cooling within the building and any surplus heat from the absorber may also be used to heat water or create ventilation.

1. A window unit comprising;
at least one transparent pane;
a frame around the perimeter of the at least one transparent pane;
at least one rotatable linear concave mirror extending at least partially across the frame; and
at least one energy conversion device extending at least partially across the frame;
wherein the unit is arranged such that substantially parallel radiation incident on the mirror is reflected onto the energy conversion device.

2. A window unit according to claim 1 further comprising a lens extending at least partially across the frame, the lens being positioned between the mirror and the energy conversion device, wherein the substantially parallel radiation is reflected by the mirror onto the lens and, subsequently, directed onto the energy conversion device.

3. A window unit according to claim 1 wherein the lens distributes the radiation to provide an equal concentration of radiation across the surface of the energy conversion device.

4. A window unit according to claim 1 further comprising a means for tracking the angle of incidence of the radiation with respect to the unit and means for rotating the mirror to a position such that the incident radiation is reflected onto the energy conversion device.

5. A window unit according to claim 1 wherein the energy conversion device is a photovoltaic cell.

6. A window unit according to claim 5 further comprising a heat sink in thermal contact with the photovoltaic cell.

7. A window unit according to claim 6 wherein the mirror is positioned on the opposite side of the transparent plane from the lens, photovoltaic cell and heat sink.

8. A window unit according to claim 7 wherein the heat sink is attached to the transparent pane and the lens and photovoltaic cell are contained within the heat sink.

9. A window unit according to claim 1 wherein the energy conversion device is a conduit carrying an energy transfer medium.

10. A window unit according to any of claim 1 comprising a plurality of mirrors, the mirrors being aligned in parallel across the window and arranged as a Venetian blind.

11. A window unit according to claim 1 wherein the mirror is positioned on the opposite side of the or each transparent pane from the lens, photovoltaic cell and heat sink.

12. A window unit according to claim 1 wherein each mirror is pivoted at the frame and the mirrors are rotated by a series of gears which rotate the mirrors about their pivots.

13. A window unit according to claim 1 wherein each mirror is hung from a roller and are rotated on rotation of the roller.

14. A window unit according to claim 1 wherein the window unit contains two windows in a double glazed configuration and the mirrors are positioned between the windows.

15. A window unit according to claim 1 wherein the lens is integral with the window.

16. A window unit according to claim 6 wherein the pane comprises several strips of transparent material, the strips being separated by the heat sinks which act as glazing bars to support the strips.

17. A window unit according to claim 1 suitable for incorporation into a building.

18. An apparatus for concentrating substantially parallel radiation onto an energy conversion device comprising;
at least one linear concave mirror, the mirror being rotatable about an axis parallel to its length; and
a receiver, the receiver comprising a lens and an energy conversion device,
wherein the apparatus is arranged such that radiation incident on the mirror is reflected onto the lens and, subsequently, directed onto the surface of the energy conversion device.

19. An apparatus for concentrating substantially parallel radiation onto an energy conversion device comprising;
at least one energy conversion device;
at least one linear concave mirror, the mirror being rotatable about an axis parallel to its length and being positioned such that the mirror can be rotated to reflect incident radiation onto the energy conversion device;
means for tracking the angle of incidence of the radiation with respect to the apparatus, and,
means for rotating the mirror to a position such that the incident radiation is reflected onto the energy conversion device.

20. (canceled)
